(19) United States
(12) Patent Application Publication
(10) Pub. No.: US 2014/0090694 A1
(43) Pub. Date: Apr. 3, 2014

(54) Reconfigurable Photovoltaic Panels

(71) Applicant: BOARD OF TRUSTEES OF MICHIGAN STATE UNIVERSITY, East Lansing, MI (US)

(72) Inventor: Marcos Bolanos, Arlington, VA (US)

(73) Assignee: BOARD OF TRUSTEES OF MICHIGAN STATE UNIVERSITY, East Lansing, MI (US)

(21) Appl. No.: 14/037,787

(22) Filed: Sep. 26, 2013

Related U.S. Application Data
(60) Provisional application No. 61/706,831, filed on Sep. 28, 2012.

(51) Int. Cl. H01L 31/05

(52) U.S. Cl. CPC H01L 31/05
USPC 136/251; 136/244

(57) ABSTRACT

A photovoltaic panel system is reconfigurable. In another aspect, multiple photovoltaic modules are removably attachable in a linear manner via interfacing male and female electrical connectors and/or magnetic electrical connectors. A further aspect of the present system provides additive collective voltage increases by plugging in multiple photovoltaic modules along one axis while also providing additive collective current increases by connecting these and/or other photovoltaic modules along a generally perpendicular axis.

### CROSS-REFERENCE TO RELATED APPLICATIONS

This application claims priority to U.S. Provisional Application Ser. No. 61/706,831, filed on Sep. 28, 2012, which is incorporated by reference herein.

### BACKGROUND AND SUMMARY

The present invention relates generally to photovoltaic panels and more particularly to a reconfigurable photovoltaic panel and electrical connector system.

Various portable and modular solar panel configurations are known. For example, reference should be made to U.S. Patent Publication No. 2012/0235477 entitled “Modular Portable Energy System” to Korman; U.S. Patent Publication No. 2011/0290307 entitled “Modular Solar Panel System” to Workman et al.; and U.S. Pat. No. 6,476,311 entitled “Portable Multiple Power Supply Comprising Solar Cell” to Lee et al. The preceding patents and patent publications are all incorporated by reference herein. These traditional constructions are disadvantageous by requiring complex connections between panels and/or requiring outer retention cases, which thereby increases cost, potential failure modes, and extra assembly steps. Furthermore, when one of these conventional solar panel cells is damaged, the entire system must typically be replaced which is especially disadvantageous when used in a portable manner which is more prone toward abuse.

In accordance with the present invention, a photovoltaic panel system is reconfigurable. In another aspect, multiple photovoltaic modules are removably attachable in a linear manner via interfacing male and female electrical connectors and/or magnetic electrical connectors. A further aspect of the present system provides additive collective voltage increases by plugging in multiple photovoltaic modules along one axis while also providing additive collective current increases by connecting these and/or other photovoltaic modules along a generally perpendicular axis. In yet another aspect, a foam-backed glass photovoltaic cell is employed with outwardly projecting electrical connectors. Another aspect of the present system uses a flexible photovoltaic cell with attached electrical connectors.

The present photovoltaic system is advantageous over traditional constructions. For example, the reconfigurability and interchangeability of the photovoltaic modules allow for easy and quick replacement of only a failed or broken module with another in a very fast (for example, less than 10 seconds for disassembly and assembly) and tool-free manner. It is also advantageous that the specific electrical connectors disclosed removably secure adjacent modules together along any edge of the photovoltaic modules while also providing the electrical interface therebetween in a multifunctional manner. Furthermore, the solar modules can be snapped together in an infinite stacked quantity to increase electrical generation depending upon the specific power requirements of an attached portable electrical device. The present system is ideally suited for lightweight and removable fastening to a flexible bag such as a backpack, the roof of an automotive vehicle, the roof of a building structure, or a water craft such as a recreational boat. Additional advantageous and features of the present invention will be ascertained from the figures, description and appended claims.

### BRIEF DESCRIPTION OF THE DRAWINGS

FIG. 1 is a perspective view showing the present photovoltaic panel system attached to a backpack;

FIG. 2 is a perspective view showing the photovoltaic panel system attached to an automotive vehicle;

FIG. 3 is a perspective view showing the photovoltaic panel system attached to a building structure;

FIG. 4 is a perspective view showing a photovoltaic module employed in the photovoltaic panel system;

FIGS. 5A and 5B are perspective views showing electrical connectors employed in the photovoltaic panel system;

FIG. 6 is a cross-sectional view, taking along line 6-6 of FIG. 4, showing the photovoltaic module;

FIG. 7 is a perspective view showing a set of the photovoltaic modules exploded apart along a first axis;

FIG. 8 is a perspective view showing a set of the photovoltaic modules exploded apart along a second and generally perpendicular axis;

FIG. 9 is a perspective view showing an array of exploded apart photovoltaic modules;

FIG. 10 is an electrical diagram showing three photovoltaic modules; and

FIG. 11 is a perspective view showing a pair of photovoltaic modules employing an alternate embodiment type of electrical connectors.

### DETAILED DESCRIPTION

Referring to FIGS. 1, 4 and 5, a preferred embodiment of a reconfigurable photovoltaic panel system 21 includes multiple photovoltaic or solar modules 23 which are connected to a portable electronic device 25 through a flexible wire 27. Each photovoltaic module 23 includes a photovoltaic cell 31 having a peripheral edge 33 thereof, at least a majority of which is encapsulated or surrounded by a polymeric casing or frame 35. In one construction, photovoltaic cell 31 includes a flexible polymeric sheet made from polyethylene, EPDM, ABS, or the like. In another configuration, as shown in FIG. 5, photovoltaic cell 31 is a thin and rigid sheet of glass backed by an open cell but stiff foam 37, which is at least 10 times as thick as the adjacent photovoltaic cell 31, which is approximately 1/16^{th} of an inch thick. Each photovoltaic module 23 is preferably no larger than three inches by six inches by one-half inch to allow for a portable array. Casing 35 is preferably an epoxy material. Foam 37 and casing 35 serve to reinforce, protect and deter breakage of glass photovoltaic cell 31.

Furthermore, a set of fasteners 39, such as hook-and-loop fasteners, snapped together clasps, hooks, adhesive or other attachments, serve to removably attach a back side of casing 35 to a flexible fabric, leather or vinyl carrying bag, such as a backpack 41. In the present example, electronic component 25 is a hand-held communications device, such as a cellular telephone, computer, audio visual device or the like, which is temporarily carried within a pocket of the backpack 41. Photovoltaic cell 31 can be made in accordance with U.S. Pat. No. 7,342,171 entitled “Integrated Photovoltaic Roofing Component and Panel” which is issued to Kahouri et al. on Mar. 11, 2008 and U.S. Pat. No. 6,307,145 entitled “Solar Cell Module” which issued to Kataoka et al. on Oct. 23, 2001, both of which are incorporated by reference herein.

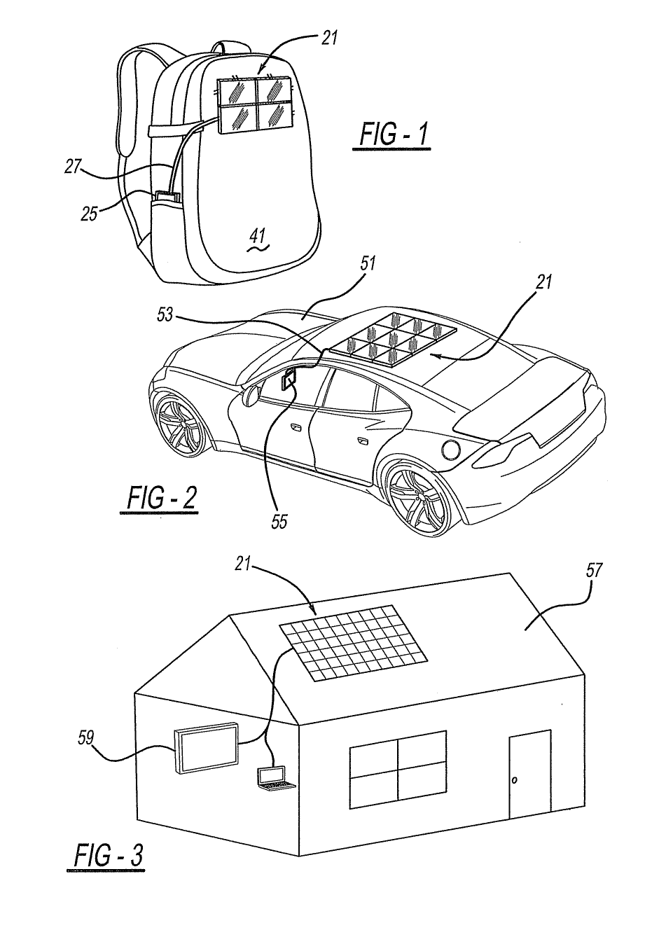

FIG. 2 illustrates an array of the reconfigurable photovoltaic panels 21 removably attached to a roof or other exterior surface of an automotive vehicle 51. A flexible wire 53 supplies electricity generated by the photovoltaic panels 21 to an internal electronic device, such as a global positioning system display 55, communications device, audio visual device or the like. Moreover, a structural building 57 is illustrated in FIG. 3 upon which is attached an array of reconfigurable photovoltaic panels 21. The panels are connected to electronic devices 59, such as a television, computer or the like within the building structure. The reconfigurable photovoltaic panels 21 can be removably attached to the roof or other exterior wall of the building structure by way of roof clamps, screw-in brackets or the like.

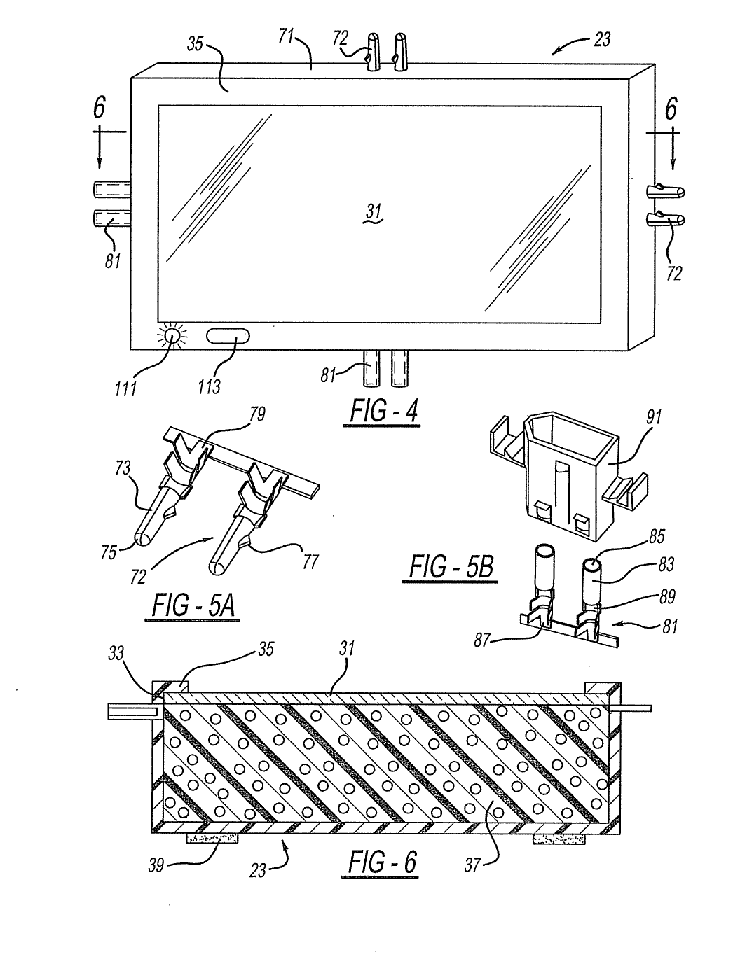

Returning to FIGS. 4-6, one or more electrical connectors outwardly protrudes from each peripheral edge 71 of each photovoltaic module 23. In the exemplary module shown, a pair of male electrical connectors 72 extend from a top edge, a pair of female electrical connectors 81 extend from an opposite bottom edge, a pair of male electrical connectors 72 extend from one side edge while a pair of female electrical connectors 81 extend from the opposite side edge. The male electrical connectors preferably have a slightly tapered, frusto-conical distal section 73 which is matable with a female connector, and a rounded or pointed distal end 75. Mating section 73 has a generally circular cross-sectional shape. A barb or knob 77 laterally protrudes from a side of mating section 73 and a proximal flat section 79 is affixed to a back side of photovoltaic cell 31 by soldering or other permanent method.

Female electrical connector 81 includes a substantially circular-cylindrical, mating barrel section 83 with an open end 85 operable to receive tapered mating section 73 of male connector 72 therein. A generally flat proximal section 87 is connected to the back side of photovoltaic cell 31 by soldering or the like. Barb 77 slightly spreads apart barrel section 83, which is stamped and bent metal, during entry and then barb 77 snaps into an open intermediate section 89 of female connector 81; this supplies a snap-in connector-to-connector retention force greater than the extraction force.

The proximal end of each electrical connector is located between the glass photovoltaic cell 31 and adjacent foam 37 when the rigid glass construction is employed. The mating portions 73 and 83 of the male and female electrical connectors, respectively, protrude through openings in the encapsulating casing 35. Both electrical connectors 72 and 81 have a length at least twice as large as width. Optionally, a polymeric socket 91 can be secured around an outside of either or both female and male electrical connectors to supply an extra or alternative snap-fit engagement with an opposite mating polymeric socket, with a barb and flexible arm snap-fit type arrangement engaging into a slot or lateral surface.

It is noteworthy that the male electrical connectors 72 from one photovoltaic module 23 are insertable into the female electrical connectors 81 of an adjacent photovoltaic module 23 in a generally linear and tool-free manner. These electrical connectors (with or without the optional socket) also have a multi-functional role by serving as the sole structure for removably securing together the adjacent photovoltaic modules while also carrying electricity between adjacent modules. The simplicity of this design allows for easy and quick detachment and then reattachment in a reconfigurable manner in less than 10 seconds without requiring the use of any threaded fasteners, welding, soldering or any tools.

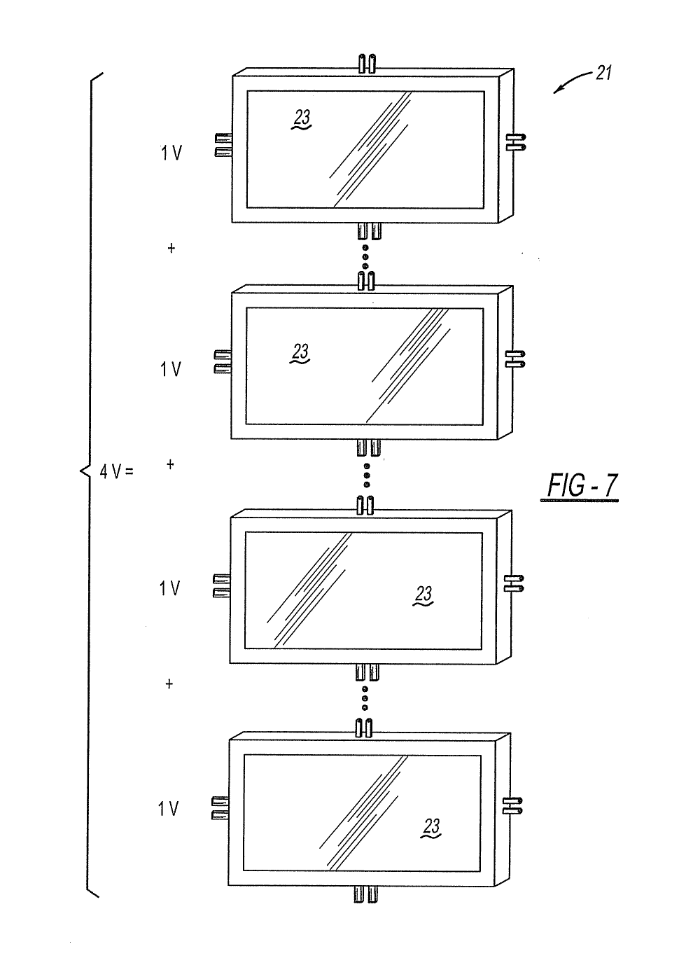

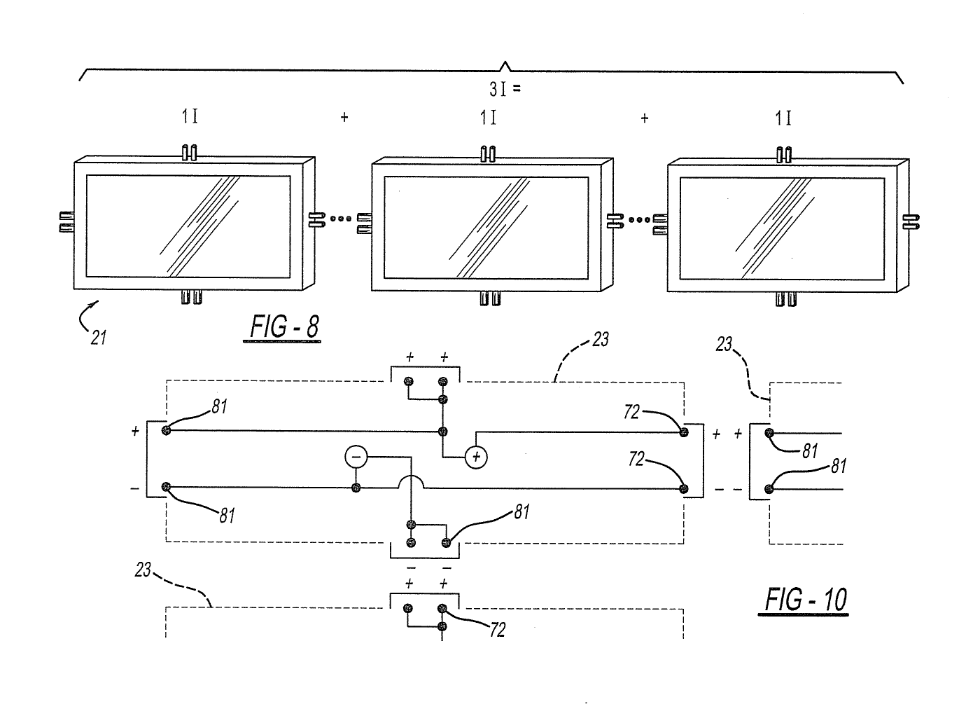

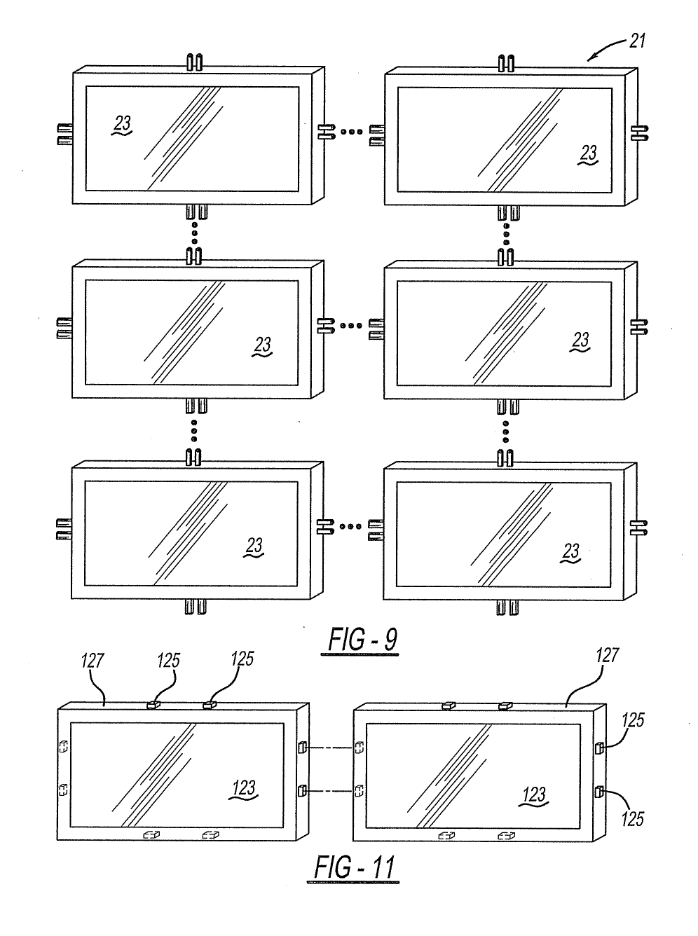

Any quantity of photovoltaic modules 23 can be attached together in the manner previously described. Various array configurations are shown in FIGS. 7-9. When the modules are arranged along one axis, such as that shown in FIG. 7, the voltage is additively increased with each module contributing to the total system voltage. Conversely, when each module is attached along an offset and perpendicular axis, such as that as illustrated in FIG. 8, each module adds to the total system current. Moreover, when the modules are attached along both axes, such as that portrayed in FIG. 9, both voltage and current are increased by each additional module attached to provide the power generation needs of the specific electronic device(s) to be powered. For example, for the cellular telephone version of FIG. 1, five photovoltaic modules can be vertically stacked together to provide five DC volts or six panels can be interconnected to provide six volts, while only two to five modules may be needed along the offset axis to provide between 200-500 milliamps and more preferably 330 milliamps for the cellular telephone use. Meanwhile, if a laptop computer is to be operated based on the photovoltaic panel system, then the user can simply connect on additional photovoltaic modules along both axes with the same connecting wire 27 being connected to a single pair of electrical connectors (the same that would otherwise interconnect with an adjacent module), or through an adaptor which may connect to multiple pairs of the module electrical connectors. A voltage limiter, diodes and other electronics may additionally be employed in an adapter. The electrical schematic arrangement between the reconfigurable photovoltaic modules is shown best in FIG. 10.

FIG. 4 illustrates a status indicator option wherein an LED indicator light 111 and an interface button or switch 113 are mounted to casing 35. When a user wants to ascertain the charging status and capability of the specific module 23 then he or she pushes button 113 which completes a diagnostic circuit for illuminating light 111 if the desired condition is present. The illumination may alternately be a display on glass photovoltaic cell 31 or a graduated and elongated bar which shows full or partial power generating capability and health. If the user finds that one of the modules 23 in the system array 21 is faulty (the light does not illuminate) then that module can easily be removed and replaced by any of the other identically configured modules in its place. This serves to provide a low cost and robust power generation system with reconfigurable “plug and play” type interconnections for use in a portable environment where a trained electrician is not needed when reconfiguration is desired.

An alternate embodiment is shown in FIG. 11. Each photovoltaic module 123 is constructed as previously disclosed, however, a different electrical connector arrangement is employed. All of the electrical connectors 125 between adjacent modules 123 in the present embodiment have a generally flat and cube-like mating surface or pad protruding through their cases 127. The mating pad of each electrical connector is magnetic such that it will attract an opposite electrical connector from a different module for use along one of the desired axes. Thus, the magnetic nature of the electrical connectors serves to both act as the sole way of connecting together the adjacent modules while also carrying electricity therebetween. These magnetic electrical connectors are attachable and removable in a tool-free and quick-connect manner in less than ten seconds.

While various constructions of the present reconfigurable photovoltaic panels have been disclosed, it should be appreciated that other variations are possible. For example, while stamped metal male and female electrical connectors have been disclosed, it should be understood that extruded, cast or other methods of making mating electrical connectors may be employed as long as they function like those discussed herein. Furthermore, it is envisioned that additional electronics and/or electrical circuits can be employed within each photovoltaic module as long as they function as essentially described. It is also envisioned that a single pin electrical connector can be employed along the voltage axis, however, two generally parallel electrical connectors from each edge provide a more stable module-to-module securing interconnection. Moreover, while two adjacent electrical connectors are shown on each edge of the module, it should be appreciated that additional electrical connectors may also be provided should extra stability or circuits require such. Additionally, features of each embodiment may be interchanged with and added to features of the other embodiments in an interchangeable manner; for example and not by way of limitation, the magnetic electrical connectors can be employed with the flexible or rigid photovoltaic cells, while the indicator light feature can be provided on the flexible, rigid or magnetic embodiments. Such variations are not to be regarded as a departure from the present disclosure, and all such modifications are intended to be included within the scope and spirit of the present invention.

The invention claimed is:

1. A photovoltaic panel system comprising:
a first photovoltaic module;
an electrical connector affixed to the first photovoltaic module;
at least a second photovoltaic module; and
another electrical connector affixed to the second photovoltaic module;
the photovoltaic modules being removably attachable to each other in a substantially linear direction by engaging the electrical connectors in a tool-free manner.

2. The system of claim 1, wherein the electrical connector affixed to the first photovoltaic module is a male electrical connector and the electrical connector affixed to the second photovoltaic module is a female electrical connector.

3. The system of claim 2, further comprising:
a third photovoltaic module;
another female electrical connector affixed to the first photovoltaic module; and
another male electrical connector affixed to the third photovoltaic module;
the third photovoltaic module being removably attachable to the first photovoltaic module by substantially linear insertion of the corresponding male electrical connector into the female electrical connector.

4. The system of claim 3, further comprising:
another female electrical connector affixed to a peripheral edge of the first photovoltaic module substantially perpendicular to the edges from which the other electrical connectors project; and
a fourth photovoltaic module;
another male electrical connector affixed to the fourth photovoltaic module;
the first and fourth photovoltaic modules being removably attachable by substantially linear insertion of the corresponding male electrical connector into the aligned female electrical connector; and
the attached second photovoltaic module increasing only system voltage while the fourth photovoltaic module increases only system current, with the second and fourth photovoltaic modules being attached to substantially perpendicular edges of the first photovoltaic module.

5. The system of claim 1, wherein the first photovoltaic module further comprises a glass exterior photovoltaic cell backed by foam, the foam having a thickness at least ten times that of the photovoltaic cell, and a polymeric casing surrounding at least a majority of a peripheral edge of the first module.

6. The system of claim 5, wherein the electrical connector affixed to the first module has a proximal section located between the foam and the photovoltaic cell, and a distal mating section of the electrical connector outwardly protrudes through the casing.

7. The system of claim 2, further comprising a second male electrical connector affixed to the first module removably engaging with a second female electrical connector affixed to the second photovoltaic module, the photovoltaic modules solely being removably secured together by the electrical connectors.

8. The system of claim 2, wherein all of the electrical connectors between the photovoltaic modules are stamped metal having a greater length than width and projecting substantially perpendicular from an associated edge surface of the respective photovoltaic modules, and the modules being both attachable and removeable from each other in less than ten seconds.

9. The system of claim 1, wherein the first photovoltaic module is flexible with a photovoltaic cell thereof including a polymeric sheet.

10. The system of claim 1, further comprising a flexible bag, a fastener removably attaching the photovoltaic modules to the bag, a portable electronic device carried by the bag, and a flexible wire connecting the electronic device to at least one of the electrical connectors of the photovoltaic modules.

11. The system of claim 1, further comprising an automotive vehicle, a fastener removably attaching the photovoltaic modules to the automotive vehicle, an electronic device carried by the automotive vehicle, and a flexible wire connecting the electronic device to at least one of the electrical connectors of the photovoltaic modules.

12. The system of claim 1, further comprising a building structure, a fastener removably attaching the photovoltaic modules to the building structure, a electronic device located inside the building structure, and a flexible wire connecting the electronic device to at least one of the electrical connectors of the photovoltaic modules.

13. The system of claim 1, further comprising an indicator light mounted to the first photovoltaic module and an interface button mounted to the first photovoltaic module, and a user contacting the interface button which causes the indicator light to illuminate if the first photovoltaic module is in a desired condition.

14. The system of claim 1, wherein all of the electrical connectors between the photovoltaic modules are magnetic such that only magnetism therebetween removably secures the photovoltaic modules together.

15. A photovoltaic panel system comprising:
a first photovoltaic module;
at least a first male electrical connector projecting from an edge of the first photovoltaic module;
a second photovoltaic module;
at least a first female electrical connector projecting from an edge of the second photovoltaic module;
the first and second photovoltaic modules being removably attachable to each other in a substantially linear direction by engaging the first male electrical connector into the first female electrical connector;
at least a second electrical connector projecting from an edge of the first photovoltaic module;
a third photovoltaic module;
at least a third electrical connector projecting from an edge of the third photovoltaic module;
the first and third photovoltaic modules being removably attachable to each other in a substantially linear direction by insertion of one of the second and third electrical connectors into the other of the second and third electrical connectors;
at least a fourth electrical connector projecting from an edge of the first photovoltaic module;
a fourth photovoltaic module;
at least a fifth electrical connector projecting from an edge of the fourth photovoltaic module;
the first and fourth photovoltaic modules being removably attachable by substantially linear insertion of one of the fourth and fifth electrical connectors into the other of the fourth and fifth electrical connectors;
the attached second photovoltaic module increasing system voltage while the fourth photovoltaic module increases system current, with the second and fourth photovoltaic modules being attached to substantially perpendicular edges of the first photovoltaic module, and the third photovoltaic module being attached to an edge of the first photovoltaic module opposite the second photovoltaic module; and
all of the photovoltaic modules being substantially identical and interchangeable.

16. The system of claim 15, wherein the first photovoltaic module is flexible with a photovoltaic cell thereof including a polymeric sheet.

17. The system of claim 15, wherein the first photovoltaic module further comprises a glass exterior photovoltaic cell backed by foam, the foam having a thickness at least ten times that of the photovoltaic cell, and a polymeric casing surrounding at least a majority of a peripheral edge of the first module.

18. The system of claim 15, wherein the photovoltaic modules are solely secured together by the electrical connectors, and any adjacent pair are attachable and removeable in a tool-free manner in less than ten seconds.

19. The system of claim 15, wherein each photovoltaic module is no larger than three inches by six inches by one-half inch, and generates between five and six volts, inclusive, and two hundred to five hundred milliamps, inclusive.

20. A photovoltaic panel system comprising:
a first photovoltaic module;
a second photovoltaic module removably attached to the first photovoltaic module in a quick connect and tool-free manner;
a third photovoltaic module removably attached to the first photovoltaic module in a quick connect and tool-free manner; and
at least a fourth photovoltaic module removably attached to the first photovoltaic module in a quick connect and tool-free manner;
the photovoltaic modules aligned along one axis collectively increasing only the voltage of the system while the photovoltaic modules aligned along a perpendicular axis increasing only the collective current of the system; and
the photovoltaic modules are all reconfigurable such that they can replace any of the other photovoltaic modules.
